(19) United States
(12) Patent Application Publication
(10) Pub. No.: US 2004/0012310 A1
(43) Pub. Date: Jan. 22, 2004

(54) Piezoelectric/electrostrictive device

(75) Inventors: Takahiro Katakura, Okaya-city (JP); Nobuo Takahashi, Kasugai-city (JP)

Correspondence Address: BURR & BROWN, PO BOX 7068, SYRACUSE, NY, 13261-7068, US

(73) Assignees: Seiko Epson Corporation, Shinjuku-Ku (JP); NGK Insulators, Ltd., Nagoya-City (JP)

(21) Appl. No.: 10/462,390

(22) Filed: Jun. 16, 2003

(30) Foreign Application Priority Data
Jun. 17, 2002 (JP) 2002-176372

(51) Int. Cl. H01L 41/047

(52) U.S. Cl. 310/365

(57) ABSTRACT

A piezoelectric/electrostrictive device includes: a substrate 1 including a through hole 11 in a middle; a vibration plate 2 disposed on one surface side of the substrate 1 to cover the through hole 11 thereof; a piezoelectric/electrostrictive layer 3 disposed in a surface of a side opposite to a disposed side of the vibration plate 2 onto the substrate 1 and which is deformed/driven by applying a voltage to vibrate the vibration plate 2; upper and lower electrodes 4, 5 disposed so as to hold the piezoelectric/electrostrictive layer 3 between the electrodes; and upper and lower electrode terminals 6, 7 electrically connected to the upper and lower electrodes 4, 5, respectively, wherein an outer shape of the substrate 1 is a square shape, and upper and lower electrode terminals 6, 7 are disposed in one pair of corners diagonally positioned in the square shape of the substrate 1.

### BACKGROUND OF THE INVENTION

1. Field of the Invention

The present invention relates to a piezoelectric/electrostrictive device, particularly to a piezoelectric/electrostrictive device which is preferably used as sensors of sensing apparatuses such as a sensing apparatus for sensing a residual amount or consumption of a liquid in a liquid container and whose mounting efficiency is enhanced with respect to the sensing apparatus and whose dispersion of a sensing capability is reduced.

2. Description of the Related Art

As a sensor of a sensing apparatus, for example, for sensing a residual amount or consumption of a liquid in a liquid container in which liquids such as ink are contained, a piezoelectric/electrostrictive device (actuator) is disclosed including: a piezoelectric/electrostrictive layer which is deformed/driven by applying a voltage. This piezoelectric/electrostrictive layer is deformed/driven to vibrate a vibration plate, and a change of an acoustic impedance with the vibration is sensed (e.g., a change of a resonance frequency is sensed by residual vibration) to sense a consumed state of the liquid in the liquid container (Japanese Patent Application Laid-Open No. 2001-146030).

As shown in FIGS. 2(a), 2(b), an actuator 106 described in the Japanese Patent Application Laid-Open No. 2001-146030 includes: a substrate 178 including a circular opening 161 substantially in a middle; a vibration plate 176 disposed in one surface (front surface) of the substrate 178 so as to cover the opening 161; a piezoelectric layer 160 disposed on the surface side of the vibration plate 176; upper and lower electrodes 164 and 166 which hold the piezoelectric layer 160 between both the electrodes; an upper electrode terminal 168 electrically connected to the upper electrode 164; and a lower electrode terminal 170 electrically connected to the lower electrode 166. The piezoelectric layer 160, upper electrode 164, and lower electrode 166 include circular portions as major portions. The respective circular portions of the piezoelectric layer 160, upper electrode 164, and lower electrode 166 form a piezoelectric/electrostrictive element 171.

As shown in FIG. 3, this actuator 106 is integrally incorporated in a module unit 100, and this module unit 100 is attached to a predetermined position of a liquid container such as a container of an ink cartridge for use. As shown in FIG. 3, the module unit 100 includes: a liquid container attaching portion 101 formed of a resin; and a piezoelectric device mounting portion 105 including a plate 110 and concave portion 113. The module unit 100 further includes lead wires (lead lines) 104a, 104b, actuator 106, and film 108. The plate 110 is formed of materials which do not easily rust, such as stainless steel or stainless steel alloy. For a columnar portion 116 and stage 102 included in the liquid container attaching portion 101, an opening 114 is formed in a center portion so that the lead wires 104a, 104b can be contained, and the concave portion 113 is formed so that the actuator 106, film 108, and plate 110 can be contained. The actuator 106 is bonded to the plate 110 via the film 108, and the plate 110 and actuator 106 are fixed to the liquid container attaching portion 101. Therefore, the lead wires 104a, 104b, actuator 106, film 108, and plate 110 are attached as one member to the liquid container attaching portion 101. The lead wires 104a, 104b are connected to the upper and lower electrodes of the actuator 106 to transmit a driving signal to a piezoelectric layer. On the other hand, the signal of the resonance frequency detected by the actuator 106 is transmitted to a recording device. The actuator 106 temporarily oscillates based on the driving signals transmitted from the lead wires 104a, 104b. The actuator 106 residually vibrates after the oscillation, and generates a counter electromotive force by the vibration. At this time, when a vibration period of a counter electromotive force waveform is detected, the resonance frequency corresponding to the consumed state of the liquid in the liquid container can be detected. The film 108 bonds the actuator 106 to the plate 110 so that the actuator 106 is liquid-tight. The film 108 is formed of polyolefin, and is heat-molten and bonded. The actuator 106 is bonded/fixed to the plate 110 by the film 108 in a plane form, dispersion with bonded portions is accordingly removed, and portions other than the vibration portion do not vibrate. Therefore, a change of the resonance frequency before/after the actuator 106 is bonded to the plate 110 can be reduced.

However, for the piezoelectric/electrostrictive device (actuator) 106 shown in FIGS. 2 and 3, an outer shape is rectangular. The actuator 106 is connected to connection portions 120 (see FIG. 4) of the (adhesive) film 108 and lead wires 104a, 104b, and integrally incorporated (mounted). In this case, at a positioning time, there has been a problem that each piezoelectric/electrostrictive device (actuator) 106 has to be oriented in one direction, because the actuator has a directional property based on a difference of the length between long and short sides. That is, as shown in FIGS. 4(a) and 4(b), since the outer shape of the actuator 106 is rectangular, in FIG. 4(a) the upper electrode terminal 168 and lower electrode terminal 170 are connected to the connection portions 120 of the lead wires 104a, 104b (see FIG. 3) without any problem. However, when the actuator 106 is rotated clockwise by 90 degrees (as shown in FIG. 4(b)), the connection portions 120 are connected to the upper electrode terminal 168 and lower electrode terminal 170, respectively, and a problem of erroneous connection has been caused. A width in a short-side direction is small, and it is difficult to have a sufficient a bond area (bond margin) with respect to the adhesive film 108 (see FIG. 3). By positional deviation of the film 108 (see FIG. 3), adhesive enters the opening (through hole) 161 (see FIG. 2) of the substrate 178 (see FIG. 2) at a heat press bond time, the bond area drops, and there is a problem of a drop in bond reliability.

### SUMMARY OF THE INVENTION

The present invention has been developed in consideration of the above-described problem, and an object is to provide a piezoelectric/electrostrictive device which is preferably used in a sensing apparatus such as a sensor of the sensing apparatus for sensing a residual amount or consumption of a liquid in a liquid container and whose mounting efficiency is enhanced with reference to the sensing apparatus and whose dispersion in a sensing capability is reduced.

As a result of intensive studies, the present inventors have found that to achieve the above-described object, an outer shape of a substrate (device) is formed in a square shape, upper and lower electrode terminals are disposed in a pair of corners diagonally positioned in the square shape of the substrate, mounting efficiency is accordingly enhanced, and a dispersion of a sensing capability can be reduced, and have completed the present invention. That is, according to the present invention, there is provided the following piezoelectric/electrostrictive device.

[1] There is provided a piezoelectric/electrostrictive device comprising: a substrate including a through hole in a middle; a vibration plate disposed on one surface side of the substrate to cover the through hole of the substrate; a piezoelectric/electrostrictive layer which is disposed on a side opposite to a disposed side of the vibration plate onto the substrate and which is deformed/driven by an applied voltage to vibrate the vibration plate; upper and lower electrodes disposed so as to hold the piezoelectric/electrostrictive layer between the electrodes; and upper and lower electrode terminals electrically connected to the upper and lower electrodes, wherein an outer shape of the substrate is a square shape, and the upper and lower electrode terminals are disposed in a pair of corners diagonally positioned in the square shape of the substrate.

In this constitution, a sufficient bond margin can be secured without enlarging a whole area, and dispersions of a bond capability and sensing capability by a sticking-out adhesive can be reduced. Moreover, a directional property at a mounting time is eliminated, and a mounting efficiency with respect to the sensing apparatus can be enhanced.

[2] In the piezoelectric/electrostrictive device according to the above [1], the upper and lower electrodes are electrically connected to the upper and lower electrode terminals in a state in which the upper and lower electrodes are disposed on a diagonal line connecting a pair of corners of the substrate to each other.

[3] In the piezoelectric/electrostrictive device according to the above [1] or [2], a sectional shape of the through hole of the substrate is a circular shape, outer shapes of major portions of the piezoelectric/electrostrictive layer and the upper and lower electrodes are circular shapes concentric with the through hole, and the piezoelectric/electrostrictive element and the upper and lower electrodes form a piezoelectric/electrostrictive element.

[4] In the piezoelectric/electrostrictive device according to any one of the above [1] to [3], the upper and lower electrode terminals are connected to a pair of lead wires each including a connection portion having a length such that the connection portion can electrically be connected to each of these terminals.

[5] In the piezoelectric/electrostrictive device according to any one of the above [1] to [4], dummy terminals are disposed in another pair of corners of the substrate in which the upper and lower electrode terminals are not disposed in an electrically isolated state from the upper and lower electrode terminals.

[6] In the piezoelectric/electrostrictive device according to any one of the above [1] to [5], a portion other than the connection portion of the lead wire is connected to a power supply which applies a voltage to the piezoelectric/electrostrictive layer to deform/drive the piezoelectric/electrostrictive layer, and sensing means for sensing a change of an acoustic impedance generated together with vibration by the deforming/driving of the piezoelectric/electrostrictive layer if necessary.

[7] The piezoelectric/electrostrictive device according to any one of the above [1] to [6] is attached to a liquid container for use as a sensor for sensing a residual amount or consumption of a liquid in the liquid container.

### BRIEF DESCRIPTION OF THE DRAWINGS

FIG. 1(a) is a plan view schematically showing one embodiment of a piezoelectric/electrostrictive device according to the present invention, and FIG. 1(b) is a sectional view in line A-A of FIG. 1(a);

FIG. 2(a) is a plan view schematically showing one example of a related-art piezoelectric/electrostrictive device (actuator), and FIG. 2(b) is a sectional view in line B-B of FIG. 2(a);

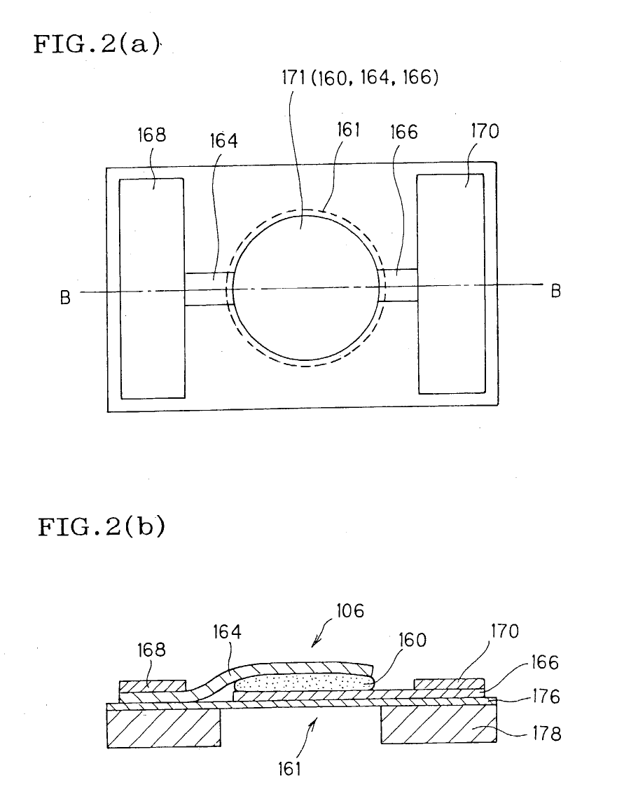

FIG. 3 is an exploded perspective view schematically showing a module unit in which the related-art piezoelectric/electrostrictive device (actuator) shown in FIGS. 2(a), 2(b) is incorporated;

FIG. 4 show plan views schematically showing a directional property based on a difference in length between long and short sides at a positioning time in mounting the related-art piezoelectric/electrostrictive device (actuator) shown in FIGS. 2(a), 2(b), FIG. 4(a) shows a connection situation of a connection portion of a lead wire to a terminal before 90-degrees rotation, and FIG. 4(b) shows a connection situation (erroneous connection) of the connection portion of the lead wire to the terminal after the 90-degrees rotation; and

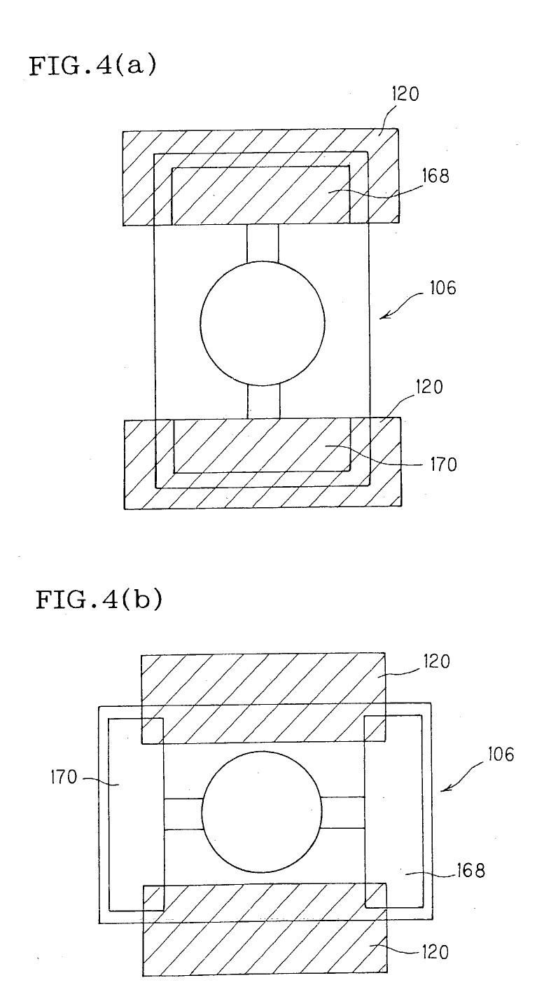

FIG. 5 show plan views schematically showing another example of a connection relation between the connection portion of the lead wire and the terminal in one embodiment of the piezoelectric/electrostrictive device according to the present invention, FIG. 5(a) shows the connection situation of the connection portion of the lead wire to the terminal before 90-degrees rotation, and FIG. 5(b) shows the connection situation between the connection portion of the lead wire to the terminal after the 90-degrees rotation.

### DESCRIPTION OF THE PREFERRED EMBODIMENT

An embodiment of a piezoelectric/electrostrictive device according to the present invention will concretely be described hereinafter with reference to the drawings.

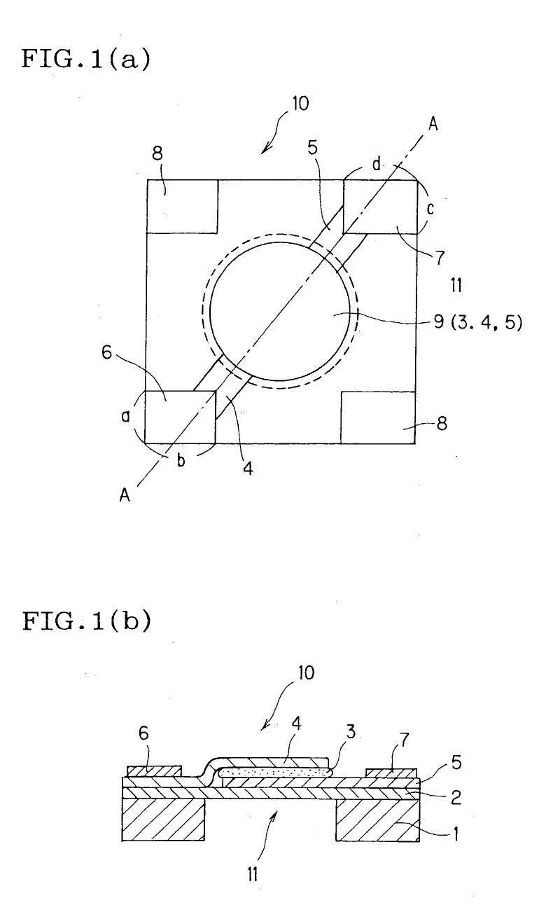

FIG. 1(a) is a plan view schematically showing one embodiment of the piezoelectric/electrostrictive device according to the present invention, and FIG. 1(b) is a sectional view in line A-A of FIG. 1(a).

As shown in FIGS. 1(a), 1(b), a piezoelectric/electrostrictive device 10 of the present embodiment includes: a substrate 1 including a through hole 11 in a middle (may slightly deviate); a vibration plate 2 disposed on one surface side of the substrate 1 so as to cover the through hole 11 of the substrate 1; a piezoelectric/electrostrictive layer 3 disposed in a surface on a side opposite to the side on which the vibration plate 2 is disposed in the substrate 1 and which is deformed/driven by applying a voltage to vibrate the vibration plate 2; an upper electrode 4 and lower electrode 5 disposed to hold the piezoelectric/electrostrictive layer 3 between the electrodes; and an upper electrode terminal 6 and lower electrode terminal 7 electrically connected to the upper electrode 4 and lower electrode 5, respectively. An outer shape of the substrate 1 is a square shape (may not be a square shape in a strict sense). Moreover, the upper electrode terminal 6 and lower electrode terminal 7 are disposed in a pair of corners which are diagonally positioned in the square shape of the substrate 1.

In this constitution, since the outer shape of the substrate 1, that is, the whole outer shape of the piezoelectric/electrostrictive device is the square shape, a sufficient bond margin can be secured without enlarging an area of the whole apparatus. Moreover, the upper electrode terminal 6 and lower electrode terminal 7 are disposed in one pair of corners which are diagonally positioned in the square shape of the substrate 1. Therefore, even when the upper electrode terminal 6 and lower electrode terminal 7 are rotated by 90 degrees, in the same manner as in a case in which the terminals are not rotated by 90 degrees, lead wires described later can be connected to connection portions without orienting the lead wires. That is, the device can be mounted without considering a directional property (by eliminating the directional property of the device), and a mounting efficiency with respect to a sensing apparatus can be enhanced.

In this case, the upper electrode 4 and lower electrode 5 are preferably electrically connected to the upper electrode terminal 6 and lower electrode terminal 7, in a state in which the electrode are disposed on a diagonal line connecting one pair of corners of the substrate 1 to each other.

In this constitution, the upper electrode 4 and lower electrode 5 having sufficient lengths can be disposed in a limited area, and mounting efficiency can be enhanced.

Moreover, a sectional shape of the through hole 11 of the substrate 1 is a circular shape, outer shapes of major portions of the piezoelectric/electrostrictive layer 3, upper electrode 4, and lower electrode 5 are circular shapes concentric with the through hole 11, and a piezoelectric/electrostrictive element 9 is preferably formed by the piezoelectric/electrostrictive layer and upper and lower electrodes.

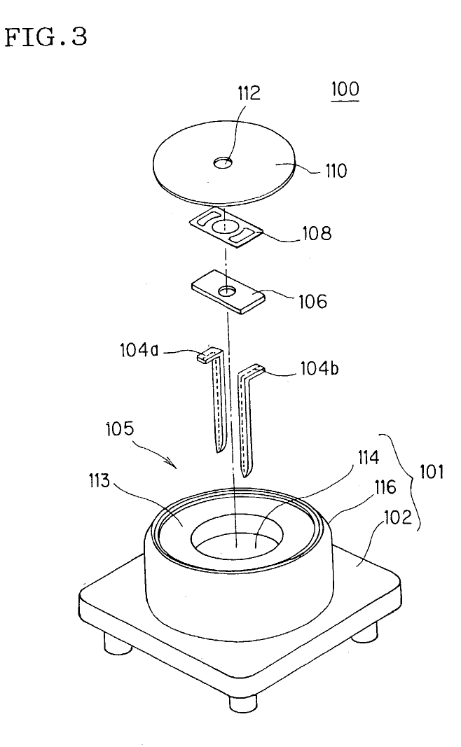

Furthermore, for the piezoelectric/electrostrictive device of the present embodiment, the upper electrode terminal 6 and lower electrode terminal 7 are connected to one pair of lead wires (see FIG. 3) including connection portions having lengths such that these lead wires can electrically be connected to the terminals.

As shown in FIGS. 1(a), 1(b), the upper electrode terminal 6 and lower electrode terminal 7 are disposed in one pair of corners diagonally positioned in the square shape of the substrate 1. In this case, the connection portions of the lead wires preferably have predetermined lengths so as to realize adequate connection to the upper electrode terminal 6 and lower electrode terminal 7, even when these terminals rotate by 90 degrees.

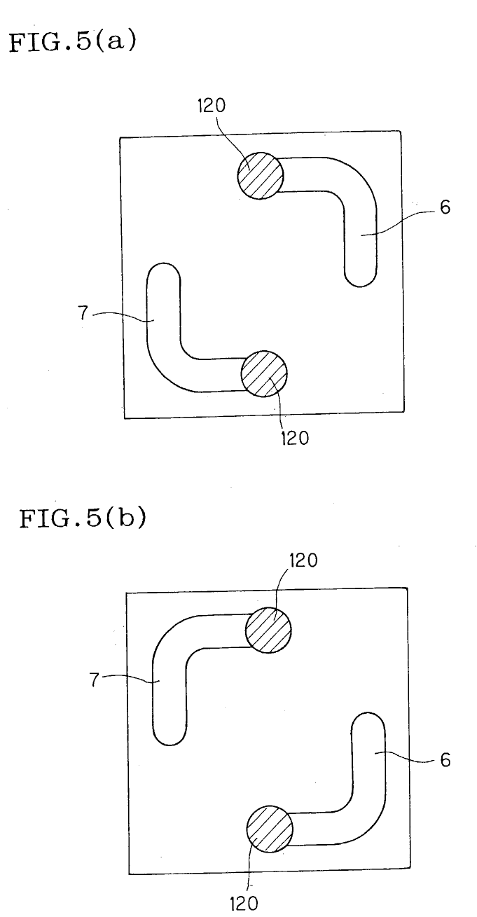

For example, assuming that the length of one side of the device 10 (substrate 1) having the square shape is s, the upper electrode terminal 6 and lower electrode terminal 7 have rectangular shapes, and the sides of the respective terminals contacting an outer periphery of the device 10 (substrate 1) are a, b, and c, d, each of the lengths of the connection portions of one pair of (two) lead wires is preferably a larger one of lengths [s−(b+c)] and [s−(a+d)]. The connection portions of the lead wires having the length can firmly be connected to the upper electrode terminal 6 and lower electrode terminal 7, even when the upper electrode terminal 6 and lower electrode terminal 7 rotate by 90 degrees. In this case, the respective connection portions of one pair of (two) lead wires are preferably linearly symmetrically constituted with respect to a center line of the device 10 (substrate 1). It is to be noted that in the above-described example, the sides a, b, c, d of the upper electrode terminal 6 and lower electrode terminal 7 contact the outer periphery of the device 10 (substrate 1). However, the sides may be positioned slightly inwards without contacting the outer periphery. The upper electrode terminal 6 and lower electrode terminal 7 may also be connected to connection portions 120 of the lead wires as shaped in FIG. 5.

Moreover, in another pair of corners of the substrate 1 in which the upper electrode terminal 6 and lower electrode terminal 7 are not disposed, dummy terminals 8 are preferably disposed in an electrically isolated state from the upper electrode terminal 6 and lower electrode terminal 7.

For thickness of the device 10, as compared with the portions in which the upper electrode terminal 6 and lower electrode terminal 7 are disposed, in the other pair of corners in which the upper electrode terminal 6 and lower electrode terminal 7 are not disposed, the device is relatively thin. In this state, flatness is insufficient. This may sometimes be an inhibiting factor, when the device is bonded to the other components. When the dummy terminals 8 having the same degrees of thicknesses as those of the upper electrode terminal 6 and lower electrode terminal 7 are disposed, the problem of the flatness can be solved. In this case, materials of the dummy terminals 8 are not especially limited, but from a viewpoint of cost, the dummy terminals are preferably formed of the same materials as those of the upper electrode terminal 6 and lower electrode terminal 7 in the same process.

For the piezoelectric/electrostrictive device of the present embodiment, portions other than the connection portions of the lead wires may be connected to a power supply which applies a voltage to the piezoelectric/electrostrictive layer to deform/drive the layer, and, if necessary, to sensing means for sensing a change of acoustic impedance caused together with vibration by the deforming/driving of the piezoelectric/electrostrictive layer.

The piezoelectric/electrostrictive device of the present embodiment is attached to a liquid container and is effectively used as a sensor for sensing a residual amount or consumption of liquid in the liquid container.

The piezoelectric/electrostrictive element for use in the present embodiment is constituted by attaching electrodes to opposite surfaces of the plate-shaped piezoelectric/electrostrictive layer, but the shape of the element is not especially limited, and examples of the shape include a rectangular shape, circular shape, and a combination of these shapes. Above all, the element preferably has the circular shape as described above.

Examples of the piezoelectric/electrostrictive layer (piezoelectric material) for use in the present embodiment include piezoelectric ceramic, but electrostrictive ceramic or ferroelectric ceramic may also be used. The material may or may not be subjected to a polarization treatment. Moreover, the layer may also be constituted of materials other than ceramic, and the piezoelectric material constituted of polymer materials represented by polyvinylidene fluoride (PVDF) or compound materials of polymer and ceramic may also be used. It is to be noted that when the polymer material is contained, the liquid to be sensed is preferably constituted not to contact the polymer material.

Examples of the piezoelectric ceramic include ceramic containing lead zirconate, magnesium lead niobate, nickel lead niobate, zinc lead niobate, manganese lead niobate, tin lead antimonate, lead titanate, barium titanate, or a mixture of these. Above all, ceramic containing lead zirconate titanate (PZT) is preferable. It is to be noted that ceramic may also contain 50% or more by mass of the above-described compound component as a main component.

Moreover, it is also possible to appropriately add additives to ceramic. For example, an oxide, arbitrary mixture, or another compound of lanthanum, calcium, strontium, molybdenum, tungsten, barium, niobium, zinc, nickel, or manganese may also be added to ceramic for use. Ceramic containing the main components of magnesium lead niobate, lead zirconate, and lead titanate, and further containing lanthanum and strontium, or bismuth-based piezoelectric ceramic may also be used.

Moreover, the piezoelectric/electrostrictive layer (piezoelectric material) may also be dense or porous. When the layer is porous, porosity is preferably 40% or less.

It is to be noted that a vibration system of the piezoelectric/electrostrictive layer (piezoelectric material) is not especially limited. When the piezoelectric/electrostrictive layer (piezoelectric material) has a plate shape, flection/displacement preferably appears in a thickness direction. An amplitude in vibrating the piezoelectric/electrostrictive layer (piezoelectric material) is preferably as small as possible. Accordingly, pulsation is prevented from being generated in fluid, and sensing accuracy can be enhanced.

Moreover, the thickness of the piezoelectric/electrostrictive layer (piezoelectric material) is not especially limited, and can variously be changed in accordance with the sensing accuracy, the type of fluid, disposed place of the sensing apparatus, and the like, but is preferably about 1 to 100 μm, more preferably about 5 to 50 μm, and most preferably about 5 to 30 μm. A multilayered structure of the piezoelectric/electrostrictive layer (piezoelectric material) and electrode may also be constituted.

The material of the electrode is not especially limited as long as the material is solid at room temperature and has electric conductivity. Examples of the material include metals or alloys containing an arbitrary combination of aluminum, titanium, chromium, iron, cobalt, nickel, copper, zinc, niobium, molybdenum, ruthenium, rhodium, silver, tin, tantalum, tungsten, iridium, platinum, gold, and lead. Above all, the electrode material preferably contains platinum group metals such as platinum, rhodium, and palladium, or alloys containing these metals, such as silver-platinum, and platinum-palladium, as the main components. From a viewpoint of durability, copper, silver, and gold are preferable.

It is to be noted that it is preferable to bond the electrode to the vibration plate without using an adhesive, when the electrode is allowed to abut on the vibration plate. From this, a high-melting metal is preferable. In this case, preferable examples of the electrode material include single metal materials or alloys containing the arbitrary combination of platinum, ruthenium, rhodium, palladium, iridium, titanium, chromium, molybdenum, tantalum, tungsten, nickel, and cobalt. Above all, the material further preferably contains the platinum group metals such as platinum, rhodium, and palladium, or the alloys containing these metals, such as silver-platinum, and platinum-palladium, as the main components from viewpoints of a high melting point and chemical stability.

Moreover, cermet containing the high-melting metal, alumina, zirconia, silica, and the like may also be used.

The thickness of the electrode is not especially limited, and is usually preferably 0.1 to 50 μm.

For a method of forming the electrode, from a viewpoint of low cost, a screen print method can be used, but sputtering, transfer, brush coating, and the like may also be used.

The vibration plate for use in the present embodiment is used to vibrate the piezoelectric/electrostrictive layer (piezoelectric material) in accordance with the deforming/driving (vibrating) of the layer. The vibration plate is not especially limited in the shape, and can variously be shaped. The thickness of the plate is preferably 1 to 100 μm, more preferably 3 to 50 μm, most preferably 5 to 20 μm.

The material of the vibration plate is not especially limited. However, for reasons that the electrode is sometimes bonded to the vibration plate by heat pressing or sintering without using any adhesive, the fluid sometimes contains an organic solvent, and that the electrode and the lead wires connected to the electrode have electric conductivity, for example, the material preferably has heat resistance, chemical stability, and insulating property.

Concretely, examples of the material include a metal which has the heat resistance and which is coated with ceramic such as glass, and ceramic per se. Above all, the material is more preferably formed of ceramic.

In this case, examples of usable ceramic may include stabilized zirconium oxide, aluminum oxide, magnesium oxide, aluminum oxide, magnesium oxide, mullite, aluminum nitride, silicon nitride, and glass. Above all, stabilized zirconium oxide is preferable. Because a high mechanical strength can be held even with the thin vibration plate, tenacity is superior, and chemical reaction to the piezoelectric/electrostrictive layer (piezoelectric material) and electrode is low.

Here, “stabilized zirconium oxide” described above contains stabilized zirconium oxide and partially stabilized zirconium oxide. Since stabilized zirconium oxide includes a crystal structure such as a cubic system, phase transition does not occur. However, zirconium oxide which is not completely stabilized causes the phase transition between a monoclinic system and tetragonal system, and cracks are sometimes generated at a phase transition.

Moreover, “stabilized zirconium oxide” contains 1 to 30 mol % of stabilizers such as calcium oxide, magnesium oxide, yttrium oxide, scandium oxide, ytterbium oxide, cerium oxide, and rare earth metal oxide, but it is preferable to contain yttrium oxide as the stabilizer for enhancing the mechanical strength of the vibration plate. In this case, a content of yttrium oxide is preferably 1.5 to 6 mol %, more preferably 2 to 4 mol %. It is to be noted that a main crystal phase of “stabilized zirconium oxide” may be a mixed system of the cubic and monoclinic systems, a mixed system of the tetragonal and monoclinic systems, a mixed system of the cubic, tetragonal, and monoclinic systems, a mixed system of the tetragonal and cubic systems, or the tetragonal system. Above all, in consideration of long reliability, the tetragonal system, or the mixed system of the tetragonal and cubic systems is preferable. Moreover, “stabilized zirconium oxide” may appropriately contain sintering aids such as MgO, Al₂O₃, SiO₂, and clay.

Moreover, ceramic constituting the vibration plate preferably contains 0.5 to 5% by mass of silicon oxide, more preferably contains 1 to 3% by mass of silicon oxide. Accordingly, when the piezoelectric/electrostrictive layer (piezoelectric material) is formed by a heat treatment, excessive reaction between the vibration plate and the piezoelectric/electrostrictive layer (piezoelectric material) is avoided by silicon oxide. Therefore, a satisfactory piezoelectric material characteristic can be obtained.

It is to be noted that when the vibration plate is formed of ceramic, a large number of crystal grains constitute the vibration plate. An average particle diameter of the crystal grains is preferably 0.05 to 2 μm, more preferably 0.1 to 1 μm in order to enhance the mechanical strength of the vibration plate.

In the present embodiment, the power supply for use if necessary, which applies the voltage to deform/drive the piezoelectric/electrostrictive layer (piezoelectric material) is not limited to a frequency variable power supply. Moreover, a frequency fixed power supply can be used whose frequency is fixed in the vicinity of the frequency with respect to a predetermined piezoelectric/electrostrictive layer (piezoelectric material). Furthermore, a self-excitation oscillation circuit may also be used without using any special frequency generating source. Above all, a system in which a vibrator is vibrated by the self-excitation oscillation circuit is preferable, because the power supply itself can inexpensively be prepared.

It is to be noted that examples of the oscillation circuit include an oscillation circuit using a transistor. Additionally, in the oscillation circuit, a CMOS inverter, TTL inverter, comparator, and the like may also appropriately be used.

As described above, according to the present invention, there can be provided the piezoelectric/electrostrictive device which is preferably used as sensors of sensing apparatuses such as a sensing apparatus for sensing a residual amount or consumption of a liquid in a liquid container and whose mounting efficiency is enhanced with respect to the sensing apparatus and whose dispersion of a sensing capability is reduced.

What is claimed is:

1. A piezoelectric/electrostrictive device comprising:
a substrate including a through hole in a middle;
a vibration plate disposed on one surface side of the substrate to cover the through hole of the substrate;
a piezoelectric/electrostrictive layer which is disposed in a surface on a side opposite to a disposed side of the vibration plate onto the substrate and which is deformed/driven by applying a voltage to vibrate the vibration plate;
upper and lower electrodes disposed so as to hold the piezoelectric/electrostrictive layer between the electrodes; and
upper and lower electrode terminals electrically connected to the upper and lower electrodes, respectively,
wherein an outer shape of the substrate is a square shape, and
the upper and lower electrode terminals are disposed in one pair of corners diagonally positioned in the square shape of the substrate.

2. The piezoelectric/electrostrictive device according to claim 1, wherein the upper and lower electrodes are electrically connected to the upper and lower electrode terminals in a state in which the upper and lower electrodes are disposed on a diagonal line connecting the pair of corners of the substrate to each other.

3. The piezoelectric/electrostrictive device according to claim 1, wherein a sectional shape of the through hole of the substrate is a circular shape, outer shapes of major portions of the piezoelectric/electrostrictive layer and the upper and lower electrodes are circular shapes concentric with the through hole, and the piezoelectric/electrostrictive layer and the upper and lower electrodes form a piezoelectric/electrostrictive element.

4. The piezoelectric/electrostrictive device according to claim 1, wherein the upper and lower electrode terminals are connected to one pair of lead wires each including a connection portion having a length such that the connection portion can electrically be connected to each of these terminals.

5. The piezoelectric/electrostrictive device according to claim 1, wherein dummy terminals are disposed in another pair of corners of the substrate in which the upper and lower electrode terminals are not disposed in an electrically isolated state from the upper and lower electrode terminals.

6. The piezoelectric/electrostrictive device according to claim 1, wherein a portion other than the connection portion of the lead wire is connected to a power supply which applies a voltage to the piezoelectric/electrostrictive layer to deform/drive the piezoelectric/electrostrictive layer, and, if necessary, to sensing means for sensing a change of an acoustic impedance generated together with vibration by the deforming/driving of the piezoelectric/electrostrictive layer.

7. The piezoelectric/electrostrictive device according to claim 1, which is attached to a liquid container for use as a sensor for sensing a residual amount or consumption of a liquid in the liquid container.
